(19) United States
(12) Patent Application Publication
(10) Pub. No.: US 2009/0212428 A1
(43) Pub. Date: Aug. 27, 2009

(54) RE-DISTRIBUTION CONDUCTIVE LINE STRUCTURE AND THE METHOD OF FORMING THE SAME

(75) Inventors: Wen-Kun Yang, Hsin-Chu City (TW); Ya-Tzu Wu, Bade City (TW); Cheng-Chieh Tai, Hsin-Chu City (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 12/035,559

(22) Filed: Feb. 22, 2008

(51) Int. Cl. H01L 23/488; H01L 21/44

(52) U.S. Cl. 257/738; 438/614; 257/E23.023; 257/E21.476

(57) ABSTRACT

A conductive line structure of a semiconductor device, the structure comprising a substrate having bonding pad; a first dielectric layer formed over the substrate; a solder pad formed over the first dielectric layer; a buffer scheme formed over the first dielectric layer and between the bonding pad and the solder pad; a conductive line formed over the buffer scheme for coupling between the bonding pad and the solder pad; a second dielectric layer formed over the conductive line to expose the solder pad; and a solder ball formed over the solder pad.

### FIELD OF THE INVENTION

This invention relates to a structure of a conductive line, and more particularly to a conductive line with a buffer scheme and the method of forming the same.

### BACKGROUND OF THE INVENTION

### Description of the Prior Art

Typically in the electronic component world, integrated circuits (ICs) are fabricated on a semiconductor substrate, known as a chip, and most commonly is made of silicon. The silicon chip is typically assembled into a larger package which serves to provide effective enlargement of the distance or pitch between input/output contacts of the silicon making it suitable for attachment to a printed circuit board, and to protect the IC from mechanical and environmental damage. With the trend moving to more and more features packed into decreasing product envelopes, utilizing ever smaller electronic components to improve upon size and feature densification a constant and formidable challenge is presented to manufacturers of consumer and related articles. Chip scale packages (CSP) were developed to provide an alternative solution to directly attached flip chip devices. These packages (CSP) represent a new miniature type of semiconductor packaging used to address the issues of size, weight, and performance in electronic products, especially those for consumer products such as mobile telephones, pagers, portable computers, video cameras, etc. Standards have not yet been formalized for CSP, and as a result many variations exist. In general, the chip is the dominant constituent of a CSP with the area of the package being no more than 20% greater than the area of the chip itself, but the package has supporting features which make it more robust than direct attachment of a flip chip.

Flip chip attachment typically utilizes ball grid array (BGA) technology. The die includes conductive external contacts, typically in the form of solder balls or bumps, arranged in a grid pattern on the active surface of the die. In a flip chip attachment, the balls of the BGA are aligned with terminals on the carrier substrate, and connected by re-flowing the solder balls. In the prior art, under-fill material is then interjected between the flip chip die and the surface of the carrier substance. High performance, low cost, miniaturization of components, and greater density of integrated circuits have long been goals of the computer industry.

A conductive film or wiring is widely used during the manufacture of the above semiconductor chips. A redistribution layer or line (RDL) is configured over the substrate to fan-out the terminal pad out of the chip to obtain suitable performance for the package.

Flip chip attachment has provided improved electrical performance and allowed greater packaging density. However, the balls are made smaller and with tighter pitches. As the balls become smaller and are set closer together, it poses problems on the flip chip. If the pitch of the bond pads is tight, it requires a redistribution layer (RDL) disposed as an intermediate layer on the surface of the die. The RDL effects an electrical interconnection (redistribution) between the bond pads on the die to the solder ball pads for communication. The die can be coupled to the solder balls through a RDL disposed on the surface of the die. The RDL functions to provide electrical connection to accommodate the die in either of these approaches. Another drawback is that damage can occur to the active surface of the die during an under-filling process onto the active surface, and molding filler can fail to flow into voids between the dies if the gap is too small.

In the prior art described in FIGS. 1, 2 and FIG. 3, a metal pad 4 is embedded within the dielectric layer 6 over a substrate 2, and a RDL metal trace 8 is connected to the metal pad 4 and extended out of the metal pad 4. A top dielectric layer 10 is covered over the dielectric layer 6 over a substrate 2, and a RDL metal trace 8 to expose under ball metal (UBM) 12. A conductive bump 14 is located over the UBM 12. FIG. 3 illustrates the top view of the RDL trace layout. An included angle with a large angle, for example 135 degrees, could be found on the RDL.

FIG. 2 illustrates the package mounted on the PCB board. In the prior art, the dielectric layer is typically the usage of BCB, PI with plastic properties. Under the scheme, the adhesion between metal 8 and dielectric layer 6 is higher than the adhesion between solder ball 14 and metal 8. The solder ball shear under test is around 300 g to 400 g for a 0.3 mm ball diameter with 300 um metal pads. The intermettalic coverage (IMC) refers to the areas indicated by A5 and A6. Under the failure mode of a ball shear test, it indicates that the solder ball will be stripped away due to brittle area occurring on the areas A5 and A6. As to the failure mode of temperature cycling test (TCT) and drop test, they also indicate that the solder ball will be destroyed in the IMC area (location A5 or A6), therefore, the solder ball material and re-flow condition are essential to the performance of the package.

In view of the aforementioned drawbacks, what is required is an improved structure and method to overcome the issues mentioned above.

### SUMMARY OF THE INVENTION

In view of the drawbacks of the prior art, the present invention provides a novel RDL structure and method to solve the aforementioned issues.

One aspect of the present invention is to form the RDL structure with a buffer scheme.

A conductive line structure of a semiconductor device, the structure comprising a substrate having a bonding pad; a first dielectric layer formed over the substrate; a solder pad formed over the first dielectric layer; a buffer scheme formed over the first dielectric layer and between the bonding pad and the solder pad; a conductive line formed over the buffer scheme for coupling between the bonding pad and the solder pad; a second dielectric layer formed over the conductive line to expose the solder pad; and a solder ball formed over the solder pad.

The buffer scheme includes a buffer layer, plurality of buffer islands or single buffer island. The buffer scheme is formed closer to the solder pad than the bonding pad. The first and second dielectric layers and buffer scheme are formed by elastic, silicone rubber type material. The buffer scheme is at least two-times the thickness of the conductive line and a multi-layer structure. The first shear strength of the conductive line and first dielectric layer/buffer layer is lower than the second shear strength of the conductive line to solder. The first shear strength is lower than 100 g and the second strength is higher than 300 g. The thickness of the conductive line is at least 6 micron meters and includes Cu/Ni/Au.

A method of forming a re-distribution layer (RDL), comprising: forming a passivation over a substrate to expose a bonding pad; forming a first dielectric layer over the passivation; forming a buffer scheme subsequently over the first dielectric layer; forming a conductive line on the buffer scheme and coupled to a solder pad, wherein the buffer scheme is formed on the area between the bonding pad and a solder pad; forming a second dielectric layer over the conductive line to expose the solder pad; forming under ball metal (UBM) on the solder pad; and forming a ball on the UBM.

### BRIEF DESCRIPTION OF THE DRAWINGS

The above objects, and other features and advantages of the present invention will become more apparent after reading the following detailed description when taken in conjunction with the drawings, in which:

FIG. 1 is a cross-sectional diagram of a conductive line structure according to the prior art.

FIG. 2 is a cross-sectional diagram of the conductive line structure according to the prior art.

FIG. 3 is a top view of the conductive line structure according to the prior art.

FIG. 4 is cross-sectional diagram according to the present invention.

FIG. 5 is cross-sectional diagram according to the present invention.

FIG. 6 is cross-sectional diagram according to the present invention.

FIG. 7 is cross-sectional diagram according to the present invention.

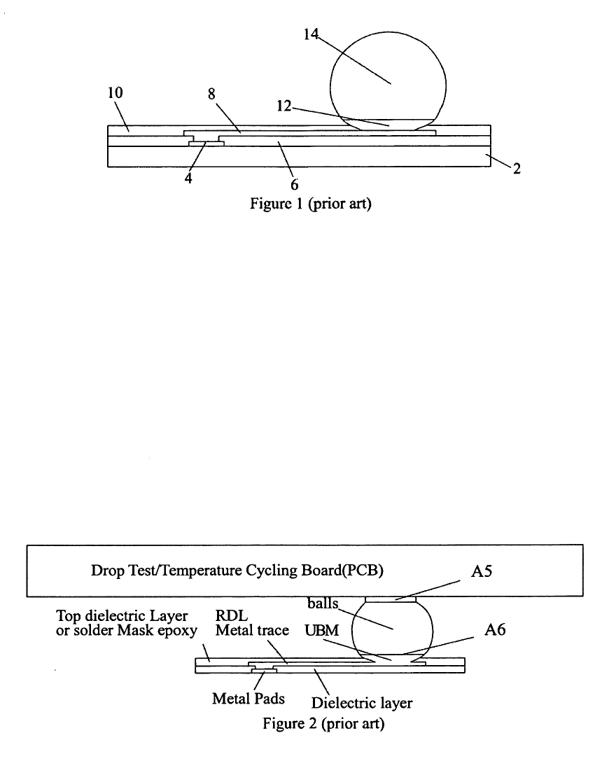

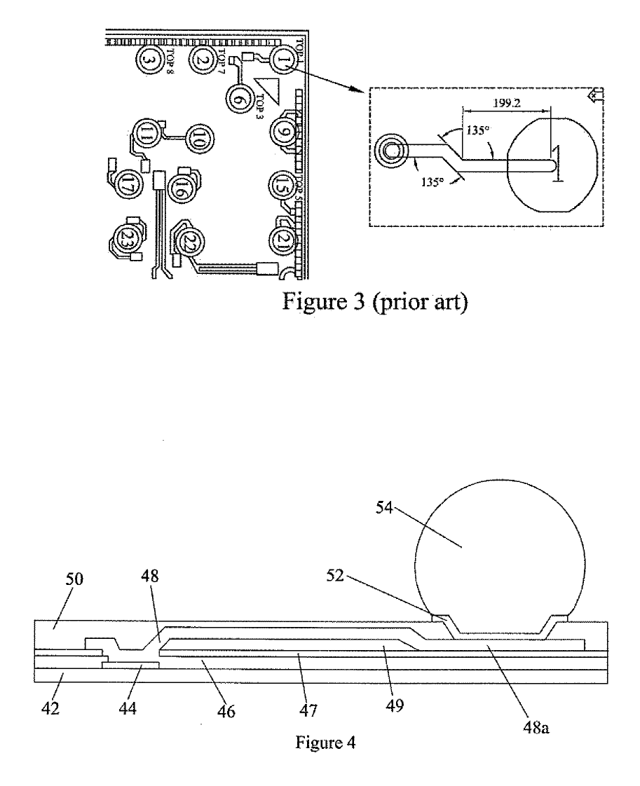

### DESCRIPTION OF THE PREFERRED EMBODIMENT

The present invention discloses an under bump metallurgy structure of a package and method of the same. It can apply to a wafer level package. Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

Referring to FIG. 4, a bounding metal pad 44 is embedded within the passivation layer 46 over a substrate 42, and a first dielectric layer (DL1) 47 is lying over the passivation layer 46 to expose the metal pad 44. In one example, the passivation is formed of PI or silicon nitride. The first dielectric layer 47 is formed of a dielectric layer with elastic property. Preferably, the first dielectric layer 47 is formed of a Silicone based dielectric (preferably, ShinEtsu SINR series or Dow Corning WL5000 series etc.).

A buffer layer 49 with elastic property is formed over the DL1 47. Preferably, the buffer layer 49 is formed of a Silicone based dielectric. In one case, the thickness of the buffer layer 49 is thicker than the thickness of the first dielectric layer 47. RDL metal (conductive) trace 48 is connected to the metal pad 4 and extended out of the metal pad 4 to solder metal pad 48a. It should be noted that the buffer layer 49 is formed on the area between the solder metal pad 48a and bounding metal pad 44, preferably, the location is near the solder metal pads. The RDL 48 between the solder metal pad 48a and bounding metal pad 44 are supported by the buffer layer 49 and it may release the thermal stress under the RDL 48 during a thermal cycle. In order to achieve higher performance, stacked elastic layers are formed between the RDL 48 and the passivation layer 46.

A top dielectric layer 50 is covered over the first dielectric layer 47 and the RDL metal trace 48 to expose UBM 52. The UBM 52 is located over the above solder metal pad 48a. A conductive bump 54 is located over the UBM 52.

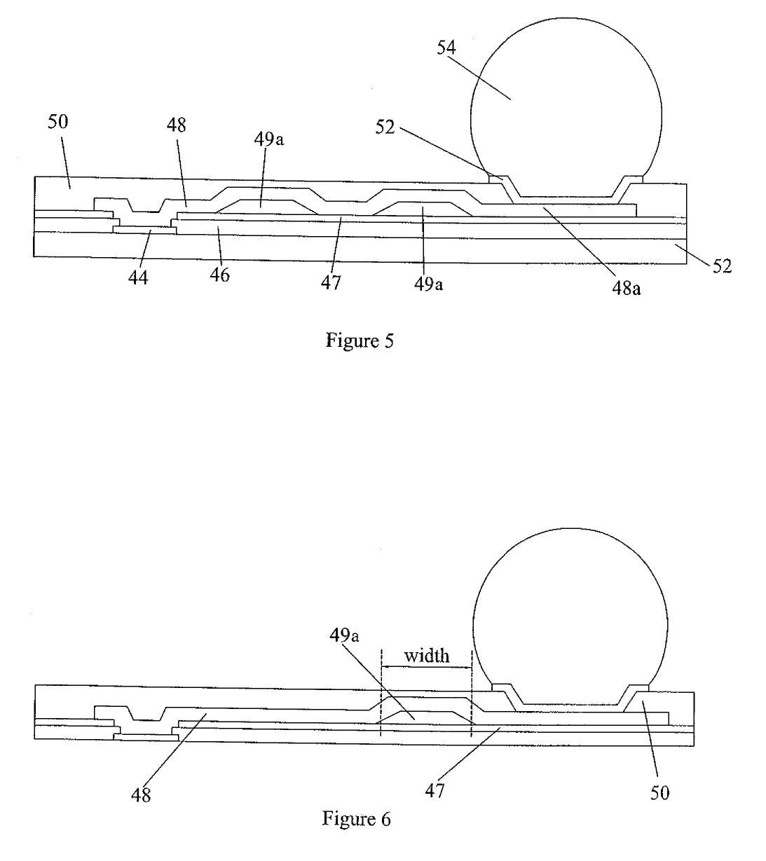

FIG. 5 illustrates another embodiment of the present invention. It indicates that pluralities of buffer islands 49a replace the buffer layer and are located over the DL1 47 and under the RDL metal trace 48. The individual buffer islands 49a may release the local thermal stress, respectively. It is because each of the buffer islands 49a may function independently to release local thermal stress, that it may achieve a better thermal releasing result. In one case, the cross-sectional view of the buffer island is trapezoid.

FIG. 6 illustrates a further embodiment of the present invention. It indicates a single one buffer island 49a is used and in this situation, the present invention suggests that the buffer island 49a is located adjacent to the solder metal pad 48a. The thin DL1 is formed of silicone rubber modified type with elastic elongation that is greater than 30%. The adhesion with metal is poor, the CTE is greater than 100 ppm and the young's modulus is low, for example, lower than 100 MPa. The buffer island 49a is formed of silicone rubber modified type with elastic elongation that is greater than 30%. The thickness is around half of the thickness of the top dielectric layer. The width of the buffer island is at least about two-times the thickness of the RDL. The adhesion with metal is poor. Further, the RDL is sputtered by seed metal, such as Ti/Cu, and E-plating metal such as Cu/Ni/Au. The thickness is greater than 6 micron meters (preferably, 9 um with Cu=6 um, Ni=3 um and Au=0.2 um). The width may be adjustable by layout. The top DL is formed of silicone rubber modified type with elastic elongation that is greater than 30%. The adhesion with DL1 is good, the CTE is greater than 100 ppm and the young's modulus is low, for example, lower than 100 MPa.

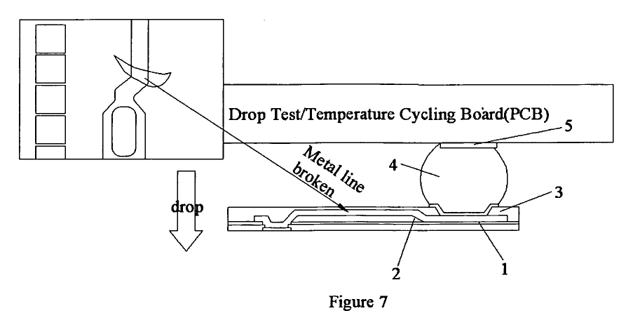

During the drop testing/Temperature Cycling Test (TCT) condition, as shown in FIG. 7, the stress initially occurs at location 3 and is trying to hold the metal because DL1 is elastic. Then, the location 1 will be the area that has similar stress as the location 3 and the solder metal pads (RDL ending) starts to peel from the DL1. Subsequently, the peeling area will extend to the buffer area at the location 2. Then, the RDL metal trace suffers stress at location 2 area, and the stress will be released or absorbed by the buffer layer. The RDL metal suffers the stress continuously and peeling from the DL1 and the top DL, the stress will be along the metal until the weak point is found and causing metal to break. The buffer under the RDL is configured as a layer type or island scheme.

One example process of forming the structure includes providing a semiconductor substrate. A passivation 46 is formed over the substrate to expose the bonding pad 44. A multi-elastic layers 47 (DL1) and 49 (buffer layer) are subsequently formed over the passivation 46. It should be noted that the buffer layer (or buffer island) is formed on the area between bonding pad and solder metal pad, preferably, it is closer to the solder metal pads. RDL layer 48 is next formed on the buffer layer or buffer island. In one embodiment, the RDL includes a multi-layer structure that is constructed by sputtered seed layer Ti/Cu, and electroplating Cu/Ni/Au. Subsequently, photo-resist (PR) is formed over the RDL, followed by patterning the PR 216 by a lithography process to obtain the pre-determined pattern. Then, the RDL is etched by using the PR as a mask. Then, the PR is stripped.

The top dielectric layer 50 (protection layer) is then formed to encompass the top surface of the RDL 48 and expose the solder metal pad. It is preferred to use the same kind of materials of layer 47 and/or layer 49. The following steps include forming UBM 52 on the solder metal pad 49a and forming solder ball 54 over the UBM 52.

As described herein, various methods and structures have been provided which make advantageous use of an electro-less and/or electroplating process to create wiring of various shapes and dimensions. Various structures that can be made trough the use of these methods have also been provided. The methods disclosed herein can be used to create conductive lines that are found to improve some of the characteristics. These various features, taken alone or in combination, are found to have profound, beneficial effects on package reliability and lifetime.

The above description of the invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

Having described the invention, the following is claimed:

1. A conductive line structure of semiconductor device, comprising:
a substrate having a bonding pad;
a first dielectric layer formed over said substrate;
a solder pad formed over said first dielectric layer;
a buffer scheme formed over said first dielectric layer and between said bonding pad and said solder pad;
a conductive line formed over said buffer scheme for coupling between said bonding pad and said solder pad;
a second dielectric layer formed over said conductive line to expose said solder pad; and
a solder ball formed over said solder pad.

2. The structure of claim 1, further comprising a passivation layer formed under said first dielectric layer.

3. The structure of claim 1, wherein said buffer scheme includes a buffer layer.

4. The structure of claim 1, wherein said buffer scheme includes a plurality of buffer islands.

5. The structure of claim 1, wherein said buffer scheme includes a buffer island.

6. The structure of claim 1, wherein said buffer scheme is formed closer to said solder pad than said bonding pad.

7. The structure of claim 1, wherein said first dielectric layer is an elastic, silicone rubber type material.

8. The structure of claim 1, wherein said second dielectric layer is an elastic, silicone rubber type material.

9. The structure of claim 1, wherein said buffer scheme is an elastic, silicone rubber type material.

10. The structure of claim 1, further comprising a UBM formed under said solder ball.

11. The structure of claim 1, wherein the width of said buffer scheme is at least two-times the thickness of said conductive line.

12. The structure of claim 1, wherein said buffer scheme is a multi-layer structure.

13. The structure of claim 1, wherein a first shear strength of said conductive line and first dielectric layer/buffer layer is lower than a second shear strength of said conductive line to solder.

14. The structure of claim 13, wherein said first shear strength is lower than 100 g.

15. The structure of claim 13, wherein said second shear strength is higher than 300 g.

16. The structure of claim 1, wherein the thickness of said conductive line is at least 6 micron meters.

17. The structure of claim 1, wherein said conductive line includes Cu/Ni/Au.

18. A method of forming re-distribution layer (RDL) with buffer scheme, comprising:
forming a passivation over a substrate to expose a bonding pad;
forming a first dielectric layer over said passivation;
forming a buffer scheme subsequently over said first dielectric layer;
forming a conductive line on said buffer scheme and coupled to a solder pad, wherein said buffer scheme is formed on the area between said bonding pad and a solder pad;
forming a second dielectric layer over said conductive line to expose said solder pad;
forming a under ball metal (UBM) on said solder pad; and
forming a ball on said UBM.

19. The method of claim 18, wherein said buffer scheme includes a buffer layer.

20. The method of claim 18, wherein said buffer scheme includes a plurality of buffer islands.

21. The method of claim 18, wherein said buffer scheme includes a buffer island.

22. The method of claim 18, wherein said buffer scheme is formed closer to said solder pad than said bonding pad.

23. The method of claim 18, wherein said first dielectric layer is an elastic, silicone rubber type material.

24. The method of claim 18, wherein said second dielectric layer is an elastic, silicone rubber type material.

25. The method of claim 18, wherein said buffer scheme is an elastic, silicone rubber type material.

26. The method of claim 18, wherein the width of said buffer scheme is at least two-times the thickness of said conductive line.

27. The method of claim 18, wherein a first shear strength of said conductive line and first dielectric layer/buffer layer is lower than a second shear strength of said conductive line to solder.

28. The method of claim 27, wherein said first shear strength is lower than 100 g.

29. The method of claim 27, wherein said second shear strength is higher than 300 g.

30. The method of claim 18, wherein the thickness of said conductive line is at least 6 micron meters.

31. The method of claim 18, wherein said conductive line includes Cu/Ni/Au.
